(19) United States
(12) Patent Application Publication
(10) Pub. No.: US 2017/0223827 A1
(43) Pub. Date: Aug. 3, 2017

(54) FILM-LIKE PRINTED CIRCUIT BOARD, AND METHOD FOR PRODUCING THE SAME

(71) Applicant: YAZAKI Corporation, Tokyo (JP)

(72) Inventors: Maki YAMADA, Shizuoka (JP); Hiroki KONDO, Shizuoka (JP); Makoto KAMBE, Shizuoka (JP)

(73) Assignee: YAZAKI Corporation, Tokyo (JP)

(21) Appl. No.: 15/489,945

(22) Filed: Apr. 18, 2017

Related U.S. Application Data
(63) Continuation of application No. PCT/JP2015/079690, filed on Oct. 21, 2015.

(30) Foreign Application Priority Data
Oct. 23, 2014 (JP) 2014-216121
Oct. 28, 2014 (JP) 2014-219737

(51) Int. Cl. H05K 1/03; H05K 1/09; H05K 1/18; H05K 3/12; H05K 3/32

(52) U.S. Cl. CPC H05K 1/0353; H05K 3/12; H05K 3/32; H05K 1/181; H05K 1/09; H05K 2201/0145; H05K 2201/0158

(57) ABSTRACT

A film-like printed circuit board includes: a low-melting-point resin film substrate composed of a low-melting-point resin in which a melting point is 370° C. or less; a circuit formed in a manner that a circuit-forming conductive paste applied onto the low-melting-point resin film substrate is subjected to plasma baking; an electronic component bonding layer formed in a manner that a mounting conductive paste applied onto the circuit is subjected to the plasma baking; and an electronic component mounted on the circuit via the electronic component bonding layer.

### CROSS REFERENCE TO RELATED APPLICATION

This application is a Continuation of PCT Application No. PCT/JP2015/079690, filed on Oct. 21, 2015, and claims the priorities of Japanese Patent Application No. 2014-216121, filed on Oct. 23, 2014, and Japanese Patent Application No. 2014-219737, filed on Oct. 28, 2014, the content of all of which is incorporated herein by reference.

### BACKGROUND

1. Technical Field

The present invention relates to a film-like printed circuit board, and to a method for producing the film-like printed circuit board.

2. Related Art

A printed circuit board (PCB) is a generic term for products, in each of which an electronic component, an integrated circuit (IC), a metal wire that connects these to each other, and the like are mounted in a high density on a printed wiring board (PWB) that is a plate-like component made of resin or the like. Heretofore, the printed circuit board has been used as an important component of an electronic instrument such as a computer, and has been used for a circuit for an automobile meter, an electronic instrument or the like.

In recent years, since a cabling space of an automobile has been required to be reduced, a wire harness and a component related thereto have been required to be miniaturized and thinned. Therefore, in automotive use, the printed wiring board has been required to also be used in the wire harness or the related component as well as a conventional meter circuit. Specifically, in the wire harness and such a component related thereto, a flexible printed circuit board, which is capable of being miniaturized, thinned, multi-layered and so on, has been required.

As the flexible printed circuit board, which responds to such miniaturization, thinning and multi-layering as described above, a flexible printed circuit (FPC) is known, which is a board in which an electric circuit is formed on a substrate formed by pasting a thin and soft base film having insulating properties and conductive metal such as copper foil to each other. As a base film (substrate) of the FPC, polyethylene terephthalate (PET), polyethylene naphthalate (PEN) and the like are known as well as polyimide (PI). PI has a high heat resistance, and PET and PEN are versatile, and are lower in price in comparison with PI.

Heretofore, such an FPC circuit has been formed by a subtractive method. The subtractive method is a method of pasting metal foil such as copper foil onto a substrate such as a polyimide film and forming a circuit by etching this metal foil. In order to etch the metal foil, the subtractive method requires an extremely long process composed of complicated steps such as photolithography, etching, and chemical vapor deposition (CVD). Therefore, with regard to the subtractive method, a throughput thereof, that is, a processing capacity thereof per unit time is extremely low. Moreover, in the subtractive method, it is apprehended that a waste liquid generated in the steps such as photolithography and etching may adversely affect the environment.

In contrast, it is examined to form the FPC circuit by an additive method in place of the subtractive method. The additive method is a method of forming a conductor pattern on an insulating plate such as the substrate. Plural types of specific methods as the additive method are examined, which include: a method of plating the substrate; a method of printing a conductive paste onto the substrate; a method of depositing metal onto the substrate; a method of adhering and wiring polyimide-coated electric wires onto the board; a method of adhering a pre-formed conductor pattern onto the board; and the like. The conductive paste is composed of metal powder, an organic solvent, a reducing agent, an adhesive and the like, and the conductive paste is applied to the substrate, followed by baking, whereby a circuit composed in such a manner that the metal powder is sintered can be formed. Among methods belonging to the above-described additive method, a method of printing the conductive paste (hereinafter, referred to as a “printing method”) has attracted attention as a method in which a throughput is the highest. Specifically, the printing method can form a final circuit by printing the conductive paste or conductive ink on a film-like substrate to form a circuit composed of conductive particles, and by pasting an insulating film on the film and a surface of the circuit, applying resist thereto, and so on.

However, in a case of using the conductive paste, a heat load applied to the substrate is large. For example, in a case of using a silver paste defined to be capable of being baked at the lowest temperature, and forming the circuit by heat baking using an electric furnace and the like, then it is necessary to bake the silver paste for approximately 30 minutes to 1 hour by a hot wind of 150° C. or more. That is to say, a heating temperature is high, and a heating time is long. Therefore, there has been a problem that such a film-like PET substrate or PEN substrate shrinks and melts in the case of baking the circuit.

In contrast, it is also conceived to use, as a baking method, plasma baking with a short baking time in place of the heat baking using the electric furnace or the like. There are proposed a variety of technologies for implementing plasma treatment for the printed board or the material thereof (Patent Literatures 1 to 6).
Patent Literature 1: Japanese Unexamined Patent Application Publication No. 2004-39833
Patent Literature 2: Japanese Unexamined Patent Application Publication No. H02-134241
Patent Literature 3: Japanese Unexamined Patent Application Publication No. S58-40886
Patent Literature 4: Japanese Unexamined Patent Application Publication No. S62-179197
Patent Literature 5: Japanese Unexamined Patent Application Publication No. H04-116837
Patent Literature 6: Japanese Unexamined Patent Application Publication No. 2013-30760
Patent Literature 7: Japanese Unexamined Patent Application Publication No. 2011-65749

### SUMMARY

### Technical Problem

However, heretofore, there has not been proposed a technology for forming the circuit on a surface of a film-like low-melting-point substrate made of PET, PEN or the like by using the conductive paste, and mounting the electronic component on a surface of the circuit. Moreover, there has been a problem that the above-described film-like low-melting-point substrate made of PET, PEN or the like is deformed in a case of adopting a method of mounting the electronic component in the circuit formed by applying the conductive paste or the conductive ink to the above-described film-like substrate, implementing the plasma baking therefor, and producing the FPC (hereinafter, this method is referred to as a “conventional plasma baking method”). Furthermore, in accordance with the conventional plasma baking method, it has been difficult to produce a low-resistance FPC in a short time.

The present invention has been made in consideration of the above-described circumstances, and it is an object of the present invention to provide a film-like printed circuit board capable of forming the circuit and mounting the electronic component at a low temperature in a short time by using a versatile low-melting-point base substrate, and to provide a method for producing the film-like printed circuit board.

Incidentally, heretofore, a busbar module (battery pack assembly) as an aggregate of busbars has been known. As this busbar, for example, there is known an aggregate of busbars which connect a plurality of secondary batteries in series to one another in a power supply device composed by connecting the secondary batteries in series to one another. As a specific example of the busbar module, for example, one shown in Patent Literature 7 is known. In this busbar module, electric wires as voltage detection lines are connected to the respective busbars. This busbar module can be used for a charge control of the power supply device by outputting voltage information of batteries in which the respective busbars are coupled to a peripheral instrument such as an ECU of a vehicle through the above-described voltage detection lines. It is conceivable that the above-described technology of the film-like printed circuit board and the method for producing the film-like printed circuit board are applicable to the busbar module as described above.

However, with regard to the conventional busbar module described in Patent Literature 7, it is necessary to sequentially wire the voltage detection lines to the respective busbars in a case of assembling the busbar module concerned to the power supply device, and accordingly, work for the assembly has been complicated. Therefore, in the conventional busbar module described in Patent Literature 7, there has been room of improvement for workability at an assembly time and a production time. As described above, in a structure that takes the busbar module as an example, that is, in a structure including: metal members (for example, busbars) electrically connected to connection targets (for example, batteries); and conductor layers (for example, voltage detection lines) electrically connected to the connection targets through the metal members, it is desired that a wiring structure that connects the metal members and the conductor layers to each other be able to be easily formed.

As described above, it is preferable if a printed circuit body capable of easily forming the wiring structure of: the metal members electrically connected to the connection targets; and the conductor layers.

A film-like printed circuit board according to a first aspect of the present invention has been made in order, as the above-described object of the invention, to provide the film-like printed circuit board capable of forming the circuit and mounting the electronic component thereon in a short time at a low temperature by using the versatile low-melting-point substrate. Specifically, the film-like printed circuit board according to a first aspect of the present invention includes: a low-melting-point resin film substrate composed of a low-melting-point resin in which a melting point is 370° C. or less; a circuit having a thickness of 10 to 20 μm and formed in a manner that a circuit-forming conductive paste applied onto the low-melting-point resin film substrate is subjected to plasma baking; an electronic component bonding layer formed in a manner that a mounting conductive paste applied onto the circuit is subjected to the plasma baking; and an electronic component mounted on the circuit via the electronic component bonding layer.

A film-like printed circuit board according to second aspect of the present invention is characterized in that, in the first aspect, the plasma baking for forming the circuit or the electronic component bonding layer is microwave-discharged plasma baking of irradiating plasma generated by microwave discharge.

A film-like printed circuit board according to third aspect of the present invention is characterized in that, in the first aspect, the circuit-forming conductive paste is a conductive paste that contains powder of one or more types of metal selected from the group consisting of Ag, Cu and Au, and the mounting conductive paste is a conductive paste that contains powder of one or more types of metal selected from the group consisting of Ag, Cu and Au.

A film-like printed circuit board according to a fourth aspect of the present invention is characterized in that, in any of the first aspect, a thickness of the low-melting-point resin film substrate is 50 μm or more.

A film-like printed circuit board according to a fifth aspect of the present invention is characterized in that, in any of the first aspect, the low-melting-point resin film substrate is composed of polyethylene terephthalate (PET), polybutylene terephthalate (PBT), polyethylene naphthalate (PEN), polypropylene (PP), or polycarbonate (PC).

A method for producing a film-like printed circuit board according to a sixth aspect of the present invention has been made in order, as the above-described object of the invention, to provide a method for producing the film-like printed circuit board capable of forming the circuit and mounting the electronic component thereon in a short time at a low temperature by using the versatile low-melting-point substrate. Specifically, the method for producing a film-like printed circuit board according to the sixth aspect of the present invention includs: a step of applying a circuit-forming conductive paste onto a low-melting-point resin film substrate composed of a low-melting-point resin in which a melting point is 370° C. or less, and performing plasma baking for the applied circuit-forming conductive paste, thereby forming a circuit having a thickness of 10 to 20 μm; and a step of applying an mounting conductive paste onto the circuit, placing the electronic component onto a mounting conductive paste, and performing plasma baking for the applied mounting conductive paste, thereby mounting the electronic component on the circuit via an electronic component bonding layer.

### BRIEF DESCRIPTION OF DRAWINGS

FIG. 1 is a plan view showing a schematic configuration of a printed circuit body according to a first embodiment of the present invention, and is also a schematic view for explaining a process of Step S104 of a flowchart of FIG. 3.

FIG. 2 is a cross-sectional view showing a cross-sectional shape perpendicular to a busbar array direction of the printed circuit body shown in FIG. 1.

FIG. 3 is a flowchart showing a production process for the printed circuit body according to the first embodiment.

FIG. 4 is a schematic view for explaining a process of Step S101 of the flowchart of FIG. 3.

FIG. 5 is a schematic view for explaining a process of Step S102 of the flowchart of FIG. 3.

FIG. 6 is a plan view showing a schematic configuration of a printed circuit body according to a second embodiment of the present invention, and is also a schematic view for explaining a process of Step S204 of a flowchart of FIG. 8.

FIG. 7 is a cross-sectional view showing a cross-sectional shape perpendicular to a busbar array direction of the printed circuit body shown in FIG. 6.

FIG. 8 is a flowchart showing a production process for a printed circuit body according to the second embodiment.

FIG. 9 is a schematic view for explaining a process of Step S201 of the flowchart of FIG. 8.

FIG. 10 is a schematic view for explaining a process of Step S202 of the flowchart of FIG. 8.

### DETAILED DESCRIPTION

Hereinafter, a specific description will be made of a film-like printed circuit board of this embodiment and a method for producing the film-like printed circuit board.

### [Film-Like Printed Circuit Board]

The film-like printed circuit board of this embodiment includes: a low-melting-point resin film substrate; a circuit formed on this low-melting-point resin film substrate; an electronic component bonding layer formed on this circuit; and an electronic component mounted on the circuit via this electronic component bonding layer.

### (Low-Melting-Point Resin Film Substrate)

The low-melting-point resin film substrate of this embodiment is a film-like substrate composed of a low-melting-point resin. Here, the low-melting-point resin is a resin in which a melting point is 370° C. or less, preferably 280° C. or less. The low-melting-point resin is not particularly limited; however, for example, there is used: polyethylene terephthalate (PET; a melting point is, for example, 258 to 260° C.); polybutylene terephthalate (PBT; a melting point is, for example, 228 to 267° C.); polyethylene naphthalate (PEN; a melting point is, for example, 262 to 269° C.); or polypropylene (PP; a melting point is, for example, 135 to 165° C.)

A thickness of the low-melting-point resin film substrate is usually 50 μm or more, preferably 100 μm or more. Moreover, the thickness of the low-melting-point resin film substrate is usually 200 μm or less. When the thickness of the low-melting-point resin film substrate stays within the above-described range, strength of the substrate is high, and in addition, even if plasma baking is performed in a case of forming the circuit on the low-melting-point resin film substrate or mounting the electronic component thereon, shrinkage, waviness and dissolution are less likely to occur in the low-melting-point resin film substrate.

### (Circuit)

The circuit of this embodiment is a circuit formed on the low-melting-point resin film substrate in such a manner that a circuit-forming conductive paste applied onto the low-melting-point resin film substrate is subjected to the plasma baking.

### <Circuit-Forming Conductive Paste>

The circuit-forming conductive paste is a paste, which includes metal powder and an organic solvent, and is added with a reducing agent, a variety of additives and the like according to needs. As the circuit-forming conductive paste, for example, a conductive paste is used, which includes powder of one or more types of metal selected from the group consisting of Ag, Cu and Au. Hereinafter, a conductive paste, which includes, as the metal powder, powder containing Ag as a main component, is referred to as an Ag paste, a conductive paste, which includes, as the metal powder, powder containing Cu as a main component, is referred to as a Cu paste, and a conductive paste, which includes, as the metal powder, powder containing Au as a main component, is referred to as an Au paste. Here, the fact that the powder contains metal M as a main component means that the number of moles of the metal M contained in the metal powder is largest among contents in the powder. Moreover, a conductive paste, which includes powder of metal M₁ and powder of metal M₂ as the metal powder, or a conductive paste, in which particles composing the powder include both of the metal M₁ and the metal M₂, is referred to as a M₁-M₂ paste. For example, if M₁ and M₂ are Ag and Cu, then the conductive paste is referred to as an Ag—Cu paste. As the circuit-forming conductive paste, an Ag paste and a Cu paste are preferable.

As the Ag paste, for example, there are used: Ag paste RAFS 074 (curable at 100° C.; viscosity at 25° C.: 130 Pa·S) made by Toyochem Co., Ltd.; Ag paste CA-6178 (curable at 130° C.; viscosity at 25° C.: 195 Pa·S) made by Daiken Chemical Co., Ltd.; and Ag ink Metalon (registered trademark) HPS-030LV (curable at 80 to 130° C.; viscosity exceeding 1000 cP) made by NovaCentrix Corporation. As the Cu paste, for example, Cu paste CP 700 (viscosity at 25° C.: 3 Pa·S) for through hole made by Harima Chemicals Group, Inc. is used.

The circuit-forming conductive paste is subjected to the plasma baking after being applied onto the low-melting-point resin film substrate, and thereby forms a circuit.

Note that the circuit-forming conductive paste is applied so as to coincide with a shape of the circuit. As a method of applying the circuit-forming conductive paste so that the circuit-forming conductive paste can coincide with the shape of the circuit, for example, there is used a method of applying the circuit-forming conductive paste onto a surface of the low-melting-point resin film substrate by using a printing method such as screen printing, ink jet, gravure printing and flexography.

When the applied circuit-forming conductive paste is subjected to the plasma baking, the metal powder in the paste is sintered, whereby the circuit is formed. In this way, the circuit is formed on the low-melting-point resin film substrate. An applied amount of the circuit-forming conductive paste onto the low-melting-point resin film substrate is appropriately set in response to a thickness and width of the circuit to be formed.

### <Plasma Baking>

The plasma baking is a process for heating the circuit-forming conductive paste by irradiating plasma thereonto, thereby volatilizing a volatile component such as an organic solvent in the circuit-forming conductive paste, fixing and solidifying the metal powder, and forming the circuit. The plasma baking is also referred to as plasma sintering. In comparison with usual heating/baking that does not use plasma, the plasma baking makes it possible to form the circuit with low energy in a short processing time, and accordingly, it becomes possible to use a low-melting-point resin film substrate prone to be deformed by the heating/baking.

Preferably, a type of the plasma baking for forming the circuit from the circuit-forming conductive paste is microwave-discharged plasma baking. The microwave-discharged plasma baking is plasma baking of irradiating plasma, which is generated by microwave discharge, onto an object of the plasma baking. The microwave-discharged plasma baking is capable of the plasma baking by irradiating plasma onto the object without physically contacting the object. Thus, the microwave-discharged plasma baking is preferable since it is easy to form the circuit from the circuit-forming conductive paste. As a microwave for use in the microwave-discharged plasma baking, a microwave with a frequency of approximately 2450 MHz is usually used.

In a case of using the microwave-discharged plasma baking, as process gas serving as a plasma generation source, for example, one or more types selected from the group consisting of hydrogen gas (H₂), nitrogen gas (N₂), helium gas (He) and argon gas (Ar) are used.

In a case of using the microwave-discharged plasma baking, power of the microwave that generates plasma is, for example, 2 to 6 kW, preferably 3 to 5 kW. When the power of the microwave stays within the above-described range, it is possible to form the circuit without breaking the circuit-forming conductive paste, and this is preferable. Moreover, in such a case where the power of the microwave is within the above-described range, a time of the plasma baking is, for example, 0.5 to 5 minutes, preferably 1 to 4 minutes.

With regard to the circuit formed in such a manner that the circuit-forming conductive paste is subjected to the plasma baking, for example, a line width thereof becomes 1 to 2000 μm, and a height thereof becomes 0.1 to 100 μm.

### (Insulating Cover Layer)

Note that, on the surface of the low-melting-point resin film substrate, on a portion on which the circuit is not formed, an insulating cover layer may be formed in order to enhance insulating properties among lines of the circuit. For example, the insulating cover layer is formed by three methods which follow.

A first insulating cover layer forming method is a method of forming the insulating cover layer after the circuit is formed and before the electronic component is mounted. Specifically, the first insulating cover layer forming method is a method of forming the circuit by applying the circuit-forming conductive paste onto the surface of the low-melting-point resin film substrate and performing the plasma baking for the circuit-forming conductive paste concerned, thereafter, forming the insulating cover layer, applying a mounting conductive paste onto the circuit, placing the electronic component on this paste, and performing the plasma baking again, thereby mounting the electronic component on the circuit.

A second insulating cover layer forming method is a method of forming the insulating cover layer after the electronic component is mounted onto the circuit. Specifically, the second insulating cover layer forming method is a method of forming the circuit by applying the circuit-forming conductive paste onto the surface of the low-melting-point resin film substrate and performing the plasma baking for the circuit-forming conductive paste concerned, thereafter, applying the mounting conductive paste onto the surface of the circuit, and placing the electronic component onto this paste, and mounting the electronic component on the circuit by performing the plasma baking again, and thereafter, forming the insulating cover layer.

A third insulating cover layer forming method is a method of mounting the electronic component on the circuit by performing the plasma baking simultaneously for the circuit-forming conductive paste and the mounting conductive paste, and thereafter, forming the insulating cover layer. Specifically, the third insulating cover layer forming method is a method of applying the circuit-forming conductive paste to the surface of the low-melting-point resin film substrate, subsequently applying the mounting conductive paste thereto, placing the electronic component thereon, performing the plasma baking to form the circuit and mount the electronic component, and thereafter, forming the insulating cover layer.

In a case of using the first insulating cover layer forming method, the insulating cover layer is subjected to the plasma baking. Therefore, in the case of using the first insulating cover layer forming method, heat resistance to heating in the plasma baking is required for a material composing the insulating cover layer. As the material composing the insulating cover layer, for example, an insulating film, or an insulating resist known in public is used. Note that, in a case of using the second or third insulating cover layer forming method, the insulating cover layer is not subjected to the plasma baking, and accordingly, the heat resistance to the heating in the plasma baking is not required therefor. However, even in the case of using the second or third method, if the insulating cover layer has heat resistance similar to that in the case of using the first insulating cover layer forming method, then the heat resistance of the insulating cover layer is higher, and accordingly, this is preferable.

The insulating film is film-like. In fabrication of such an insulating cover layer using this insulating film, first, an insulating film in which a hole with a shape of a mounted component is formed by a die is fabricated. Next, this insulating film is pasted onto the surface of the low-melting-point resin film substrate. In this way, an insulating cover layer penetrated by a shape of the circuit can be formed. Moreover, the insulating resist is liquid. In fabrication of such an insulating cover layer using this insulating resist, first, the insulating resist is applied to the surface of the low-melting-point resin film substrate by printing and the like, followed by drying. Next, such an insulating resist-applied object thus dried is cured to a predetermined shape by ultraviolet curing, thermal curing and the like by using masking and the like, and thereafter, an uncured portion is removed. In this way, such an insulating cover layer penetrated by the shape of the circuit can be formed.

As the insulating film, for example, there is used a film made of polyethylene terephthalate (PET), polyethylene naphthalate (PEN), polycarbonate (PC), polypropylene (PP), polybutylene terephthalate (PBT_, polyurethane (PU) or the like. These insulating films are preferable since heat resistance thereof is high.

As the insulating resist, for example, a thermosetting resist or an ultraviolet-curing resist is used. Moreover, as the thermosetting resist, for example, an epoxy-based resist or a urethane-based resist is used. These materials are preferable since heat resistance thereof after being cured is high.

### (Electronic Component Bonding Layer)

The electronic component bonding layer is a layer formed in such a manner that the mounting conductive paste applied onto the circuit is subjected to the plasma baking. This electronic component bonding layer is a layer for mounting the electronic component on the circuit. Therefore, in a case where the electronic component bonding layer is formed, the mounting conductive paste applied onto the circuit is subjected to the plasma baking in a state where the electronic component is mounted thereon, whereby not only the electronic component bonding layer is formed but also the electronic component is mounted on the circuit via the electronic component bonding layer.

### <Mounting Conductive Paste>

In a similar way to the circuit-forming conductive paste, the mounting conductive paste is a paste, which contains metal powder and an organic solvent, and is added with a reducing agent, a variety of additives and the like according to needs. For example, the mounting conductive paste is selected from those similar to the materials for the circuit-forming conductive paste, and is then used. A composition of the mounting conductive paste may be the same as or different from that of the circuit-forming conductive paste. If the composition of the mounting conductive paste and the composition of the circuit-forming conductive paste are the same, then bonding between metal particles on an interface between the circuit and the electronic component bonding layer becomes strong, and accordingly, this is preferable.

After being applied onto the circuit, the mounting conductive paste is subjected to the plasma baking, and thereby forms the electronic component bonding layer.

Note that the mounting conductive paste is applied to the portion on which the electronic component is mounted. As a method of applying the mounting conductive paste so that the mounting conductive paste can coincide with a shape of the portion on which the electronic component is mounted, for example, a method similar to that of the application of the circuit-forming conductive paste to the circuit is used. Specifically, there is used a method of forming an insulating cover layer, which is penetrated by the shape of the portion on which the electronic component is mounted, on the surface of the circuit, and then applying the mounting conductive paste onto the insulating cover layer. A forming method of the insulating cover layer is similar to the method of the application of the circuit-forming conductive paste to the circuit, and accordingly, a description thereof is omitted. An applied amount of the mounting conductive paste onto the circuit is appropriately set in response to a thickness and width of the electronic component bonding layer to be formed.

### <Plasma Baking>

Plasma baking for forming the electronic component bonding layer from the mounting conductive paste is performed in a similar way to the plasma baking for forming the circuit from the circuit-forming conductive paste. Specifically, it is preferable that a type of the plasma baking for forming the circuit be microwave-discharged plasma baking. The microwave-discharged plasma baking is capable of the plasma baking by irradiating plasma onto the object without physically contacting the object, and accordingly, is preferable since it is easy to form the electronic component bonding layer from the mounting conductive paste.

A frequency of the microwave for use in the plasma baking for forming the electronic component bonding layer from the mounting conductive paste, a type of process gas for use therein, power of the microwave, a time of the plasma baking, and the like are selected within a range similar to that in the plasma baking for forming the circuit from the circuit-forming conductive paste. Conditions for the plasma baking for forming the electronic component bonding layer from the mounting conductive paste may be the same as or different from those for the plasma baking for forming the circuit from the circuit-forming conductive paste.

### (Electronic Component)

The electronic component is mounted on the circuit via the electronic component bonding layer. The electronic component is not particularly limited, and a component known in public is used.

Moreover, with regard to the electronic component, if a plating layer is formed on a portion at least in contact with the circuit, for example, in an electrode portion, then the electronic component is mounted on the circuit more surely, and accordingly, this is preferable. Note that the plating layer may be formed on a portion other than the portion in contact with the circuit. It is preferable that a material of the plating layer formed on the surface of the electronic component be, for example, metal made composed of one or more types of metal selected from the group consisting of tin, gold, copper, silver, nickel and palladium. Note that, in a case where the material of the plating layer is composed of two or more types of these metals, the plating layer becomes an alloy of the two or more types of the metals.

The film-like printed circuit board of this embodiment is produced, for example, by a method for producing the film-like printed circuit board shown below.

### [Method for Producing Film-Like Printed Circuit Board]

The method for producing the film-like printed circuit board of this embodiment includes first and second producing methods. The first producing method includes: a circuit forming step of forming a circuit; and an electronic component mounting step of mounting an electronic component on the circuit via an electronic component bonding layer. Moreover, the second producing method includes a circuit forming/electronic component mounting step of mounting an electronic component on a circuit via an electronic component bonding layer simultaneously with forming the circuit.

### (First Producing Method)

### <Circuit Forming Step>

The circuit forming step is a step of applying a circuit-forming conductive paste onto a low-melting-point resin film substrate composed of a low-melting-point resin in which a melting point is 370° C. or less, and performing plasma baking for the applied circuit-forming conductive paste, thereby forming a circuit.

In this step, definitions and conditions of the low-melting-point resin film substrate, the circuit-forming conductive paste, the plasma baking and the circuit are the same as those of the film-like printed circuit board of the above-described embodiment, and accordingly, a description thereof is omitted.

### <Electronic Component Mounting Step>

The electronic component mounting step is a step of applying an mounting conductive paste onto the circuit, placing the electronic component onto amounting conductive paste, and performing plasma baking for the applied mounting conductive paste, thereby mounting the electronic component on the circuit via an electronic component bonding layer.

In this step, definitions and conditions of the mounting conductive paste, the plasma baking, the electronic component and the electronic component bonding layer are the same as those of the film-like printed circuit board of the above-described embodiment, and accordingly, a description thereof is omitted.

### (Second Producing Method)

### <Circuit Forming/Electronic Component Mounting Step>

The circuit forming/electronic component mounting step is a step of applying the circuit-forming conductive paste onto the low-melting-point resin film substrate composed of the low-melting-point resin in which the melting point is 370° C. or less, applying the mounting conductive paste onto this circuit-forming conductive paste, placing the electronic component onto the mounting conductive paste, and performing the plasma baking for the applied conductive pastes, thereby mounting the electronic component on the circuit via the electronic component bonding layer.

In the second producing method, definitions and conditions of the low-melting-point resin film substrate, the circuit-forming conductive paste, the mounting conductive paste, the electronic component and the electronic component bonding layer are the same as those of the first producing method, and accordingly, a description thereof is omitted.

In the second producing method, the circuit-forming conductive paste and the mounting conductive paste on which the electronic component is placed are subjected to the plasma baking simultaneously, and the electronic component is mounted on the circuit, which is obtained by the plasma baking, via the electronic component bonding layer obtained by the plasma baking. In the second producing method, conditions for the plasma baking are the same as those of the first producing method, and accordingly, a description thereof is omitted.

The first or second producing method may include an insulating cover layer forming step of forming an insulating cover layer for enhancing insulating properties between lines of a circuit on a portion on which the circuit is not formed on the surface of the low-melting-point resin film substrate of the film-like printed circuit board of the embodiment. In the first producing method, for the insulating cover layer forming step, there is used: a method performed after the circuit forming step and before the electronic component mounting step (that is, a first insulating cover layer forming method); or a method performed after the electronic component mounting step (that is, a second insulating cover layer forming method). Moreover, in the second producing method, for the insulating cover layer forming method, there is used a method performed after the circuit forming/electronic component mounting step (that is, a third insulating cover layer forming method).

As the first to third insulating cover layer forming methods, specifically, there is used: a method of pasting an insulating film to the surface of the low-melting-point resin film substrate, or a method of applying a publicly-known insulating resist to the surface of the low-melting-point resin film substrate by printing and the like, followed by drying.

### (Functions)

In the film-like printed circuit board of this embodiment and the first producing method therefor, first, the circuit-forming conductive paste is applied onto the low-melting-point resin film substrate, and is subjected to the plasma baking, whereby the circuit is formed on the low-melting-point resin film substrate in a short time at a low temperature. Next, in the first producing method, the mounting conductive paste is applied onto the circuit, and the electronic component is placed onto the mounting conductive paste, and both of the conductive pastes are subjected to the plasma baking, whereby the electronic component is mounted on the circuit via the electronic component bonding layer in a short time at a low temperature.

Moreover, in the film-like printed circuit board of the embodiment and the second producing method therefor, the circuit-forming conductive paste is applied onto the low-melting-point resin film substrate, the mounting conductive paste is applied onto this circuit-forming conductive paste, the electronic component is placed onto the mounting conductive paste, and both of the conductive pastes are subjected to the plasma baking, whereby the electronic component is mounted on the circuit via the electronic component bonding layer in a short time at a low temperature.

Therefore, in the film-like printed circuit board of the embodiment and the producing method therefor, it is possible to form the circuit and mount the electronic component thereon in a short time at a low temperature while using the low-melting-point resin film substrate as a substrate.

### [Printed Circuit Body]

Next, a description is made of a printed circuit body of this embodiment.

The printed circuit body of this embodiment includes: a metal member electrically connected to a connection target; an insulator layer having insulating properties; and a conductor layer, which integrally covers the metal member and the insulator layer, and is electrically connected to the metal member.

Moreover, it is preferable that the printed circuit body of this embodiment include a protection layer that covers and protects the conductor layer.

Furthermore, in the printed circuit body of this embodiment, preferably, the metal member and the insulator layer are formed integrally with each other, and the conductor layer is formed so as to integrally cover the metal member and the insulator layer while including a connection portion therebetween.

Moreover, preferably, the printed circuit body of this embodiment includes an insulating support body in which the metal member and the insulator layer are placed on a surface, the metal member and the insulator layer are placed on the insulating support body so as to be spaced apart from each other, and the conductor layer integrally covers the metal member, the insulating support body and the insulator layer.

Moreover, in the printed circuit body of this embodiment, preferably, the conductor layer is formed by printing.

Moreover, in the printed circuit body of this embodiment, preferably, the conductor layer is formed so as to conduct by printing a conductive paste and thereafter baking the same, and the conductive paste is any of an Ag paste, a Cu paste and an Au paste, which contain silver (Ag), copper (Cu) and gold (Au) as main metal components, respectively, and a mixed paste formed by mixing two or more types of these.

Moreover, in the printed circuit body of this embodiment, preferably, the insulator layer is formed of any of materials, which are polyvinyl chloride (PVC), polypropylene (PP), polyethylene terephthalate (PET), polyethylene naphthalate (PEN), polycarbonate (PC), polybutylene terephthalate (PBT), and polyethylene (PE).

Hereinafter, a specific description will be made of the printed circuit bodies according to the first and second embodiments with reference to the drawings. Note that, in the drawings which follow, the same reference numerals are assigned to the same or equivalent portions, and a description of configurations and functions thereof is omitted.

### First Embodiment

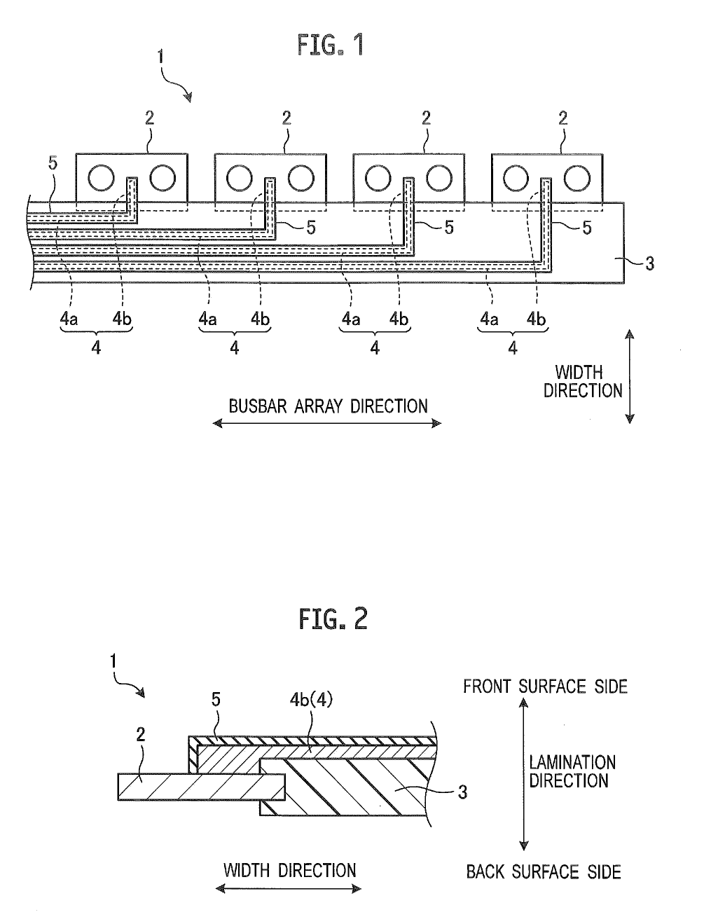

A description will be made of the printed circuit body according to the first embodiment with reference to FIG. 1 to FIG. 5. FIG. 1 is a plan view showing a schematic configuration of a printed circuit body 1 according to the first embodiment of the present invention. FIG. 2 is a cross-sectional view showing a cross-sectional shape perpendicular to a busbar array direction of the printed circuit body 1 shown in FIG. 1.

Note that, in the following description, a direction (a left-and-right direction in FIG. 1) where busbars 2 as such metal members, which are shown in FIG. 1, are arranged in parallel is written as a “busbar array direction”, and an extended direction (an up-and-down direction of FIG. 1) of a short side of an insulator layer 3 is written as a “width direction”. Moreover, a direction (an up-and-down direction of FIG. 2) where the respective elements shown in FIG. 2 are laminated on one another is written as a “lamination direction”, a side on which a resist layer 5 is disposed is written as a “front surface side”, and a side on which the busbars 2 and an insulator layer 3 are disposed is written as a “back surface side”. As shown in FIG. 2, a “width direction” in FIG. 2 is a left-and-right direction of FIG. 2.

The printed circuit body 1 according to the first embodiment, which is shown in FIG. 1 and FIG. 2, includes: metal members (busbars) 2 electrically connected to a connection target such as a battery (not shown); conductor layers 4 electrically connected to the connection target via the metal members; and the insulator layer 3. The metal members 2 and the insulator layer 3 are integrally covered with the conductor layers 4.

In this embodiment, a description is made of a configuration in a case where this printed circuit body 1 is applied as a busbar module for a power supply device. As mentioned above, the busbar module for a power supply device is used, for example, for a power supply device composed in such a manner that a plurality of secondary batteries are connected in series to one another. For example, the power supply device as described above is used as a device, which is mounted on an electric vehicle or a hybrid vehicle, supplies electric power to an electric motor, and is charged from the electric motor. Moreover, this power supply device makes it possible to obtain a high battery output, which corresponds to a required output from such a vehicle, by connecting the plurality of batteries in series to one another. In usual, the busbar module for a power supply device includes a plurality of the busbars 2. Each of the plurality of busbars 2 electrically connects a positive electrode terminal and negative electrode terminal of two batteries adjacent to each other in the power supply device. In this way, the busbar module for a power supply device is made capable of connecting a plurality of the secondary batteries in the power supply device in series to one another.

In the busbar module for a power supply device, there are provided a plurality of the conductor layers 4 as voltage detection lines for outputting pieces of voltage information of the batteries to which the respective busbars 2 are coupled. The plurality of conductor layers 4 are provided by the same number as that of the busbars 2, and each of the conductor layers 4 is connected to any one of the plurality of busbars 2. The busbar module for a power supply device outputs the pieces of voltage information of the batteries, to which the respective busbars 2 are coupled, to a peripheral instrument such as an ECU of the vehicle via the plurality of conductor layers 4. Based on the acquired pieces of voltage information, the peripheral instrument performs a charge control for the respective batteries of the power supply device.

As shown in FIGS. 1 and 2, the printed circuit body 1 includes: the busbars 2 as the metal members; the insulator layer 3; the conductor layers 4; and the resist layers 5 as the protection layers.

The busbars 2 are metal members electrically connected to connection targets such as the terminals of the batteries. The busbars 2 are formed into a rectangular plate shape. It is preferable that the printed circuit body 1 include the plurality of busbars 2. In the printed circuit body 1 shown in FIG. 1, four busbars 2 are provided with respect to the single printed circuit body 1. In a case where the busbars 2 are plural, the busbars 2 are arranged in parallel to one another at a predetermined interval along a predetermined direction. In the printed circuit body 1 shown in FIG. 1, four busbars 2 are arranged in parallel along the busbar array direction. As shown in FIG. 1 and FIG. 2, with regard to each of the busbars 2, one end side (a lower side in FIG. 1) thereof in a width direction is embedded in the insulator layer 3.

The insulator layer 3 is a substrate that has a function to be coupled to the busbar 2 via the conductor layer 4 disposed on a surface of the insulator layer 3 concerned. The insulator layer 3 is disposed so that a normal direction of a principal plane thereof can substantially coincide with a normal direction of a principal plane of each of the busbars 2. The busbars 2 and the insulator layer 3 are formed integrally with each other by insert molding. The insulator layer 3 is a band-like member extended along the busbar array direction. In a one-side end surface of the insulator layer 3, which goes along the busbar array direction, that is, in an end surface thereof in a longitudinal direction, the plurality of busbars 2 are partially embedded.

The insulator layer 3 is a layer having insulating properties. As the insulator layer 3, for example, a film, a molded product or the like, which is molded by performing injection molding for a polyvinyl chloride (PVC), can be used. Moreover, besides the above, as a material of the insulator layer 3, there can be used polypropylene (PP), polyethylene terephthalate (PET), polyethylene naphthalate (PEN), polycarbonate (PC), polybutylene terephthalate (PBT), or the like.

The conductor layers 4 are conductive elements, which are electrically connected to the busbars 2, and are thereby also electrically connected to the connection targets connected to the busbars 2. As shown in FIG. 2, each of the conductor layers 4 is formed on a front surface side in the lamination direction of the busbar 2 and the insulator layer 3 so as to integrally cover the busbar 2 and the insulator layer 3. The printed circuit body 1 includes the same number of conductor layers 4 as that of the busbars 2, and in the printed circuit body 1 shown in FIG. 1, four conductor layers 4 are provided. In a case where the conductor layers 4 are plural, each of the conductor layers 4 is individually connected to any one of the plurality of busbars 2. Each of the conductor layers 4 includes: a main line portion 4a, which is formed into a line shape, and is extended on the insulator layer 3 along the busbar array direction; and a connection line portion 4b, which is bent from this mainline portion 4a at a substantially right angle in a direction of any one of the busbars 2, and is extended in the width direction of the insulator layer 3 until reaching the front surface of the busbar 2. This connection line portion 4b of the conductor layer 4 is formed so as to integrally cover the busbar 2 and the insulator layer 3, to which the conductor layer 4 concerned are connected. Moreover, the conductor layers 4 are formed by printing. With regard to each of the conductor layers 4, a one-side end portion thereof is connected to any one of the busbars 2.

For example, each of the conductor layers 4 is formed so as to conduct by printing the conductive paste, and thereafter, baking the same. As the conductive paste, a paste can be used, which is obtained by adding an organic solvent, a reducing agent, an additive or the like to metal particles. As the metal particles, it is preferable to use silver, copper, gold, or a hybrid type obtained by combining two types or more of these with one another. That is to say, as the conductive paste, it is preferable to use an Ag paste, a Cu paste and an Au paste, which contain silver (Ag), copper (Cu) and gold (Au) as main metal components, respectively, or a mixed paste obtained by mixing two or more types of these.

As a printing method of each of the conductor layers 4, a printing technology such as screen, dispensing, ink jet, gravure, and flexography is preferable. Among them, the screen or the dispensing is preferable since a circuit width can be suitably held thereby. Moreover, it is preferable that each of the conductor layers 4 be formed by repeating the printing a plurality of times. Note that each of the conductor layers 4 can also be formed by partially repeating the printing a plurality of times.

The resist layers 5 are protection layers which cover and protect the conductor layers 4. As shown in FIG. 2, the resist layers 5 are formed on a front surface side in the lamination direction of the conductor layers 4. The printed circuit body 1 includes the same number of resist layers 5 as that of the busbars 2 and that of the conductor layers 4. In the printed circuit body 1 shown in FIG. 1, four resist layers 5 are provided. Each of the resist layers 5 is formed so as to cover an entire area of any one of the plurality of conductor layers 4. As each of the resist layers 5, for example, a thermosetting or UV-curing resist is used. It is particularly preferable to use an epoxy-based resist or a urethane-based resist.

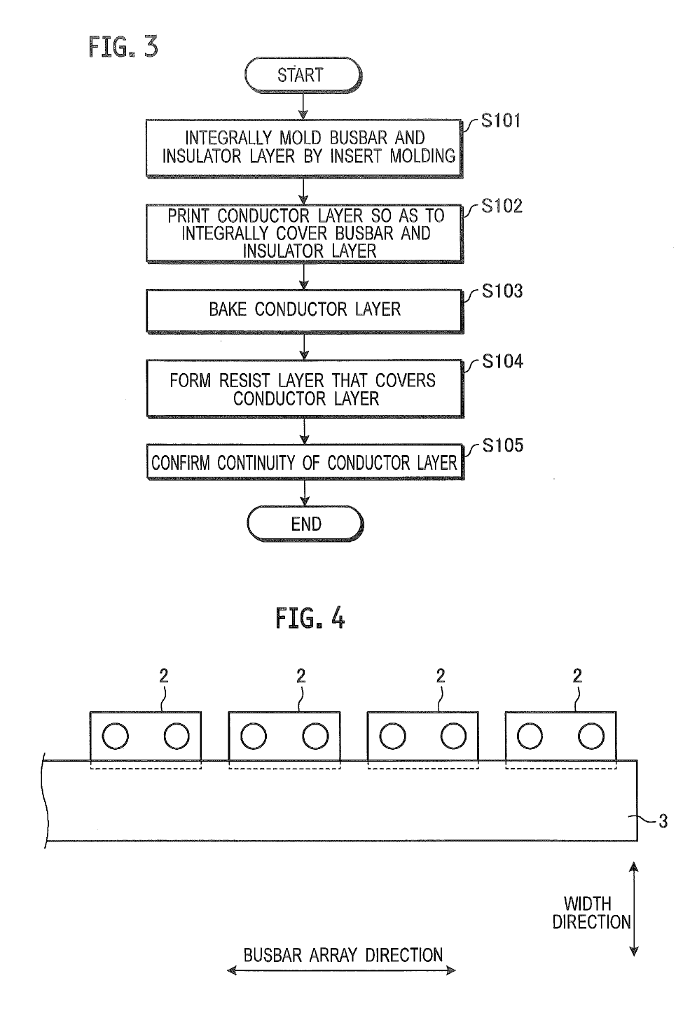

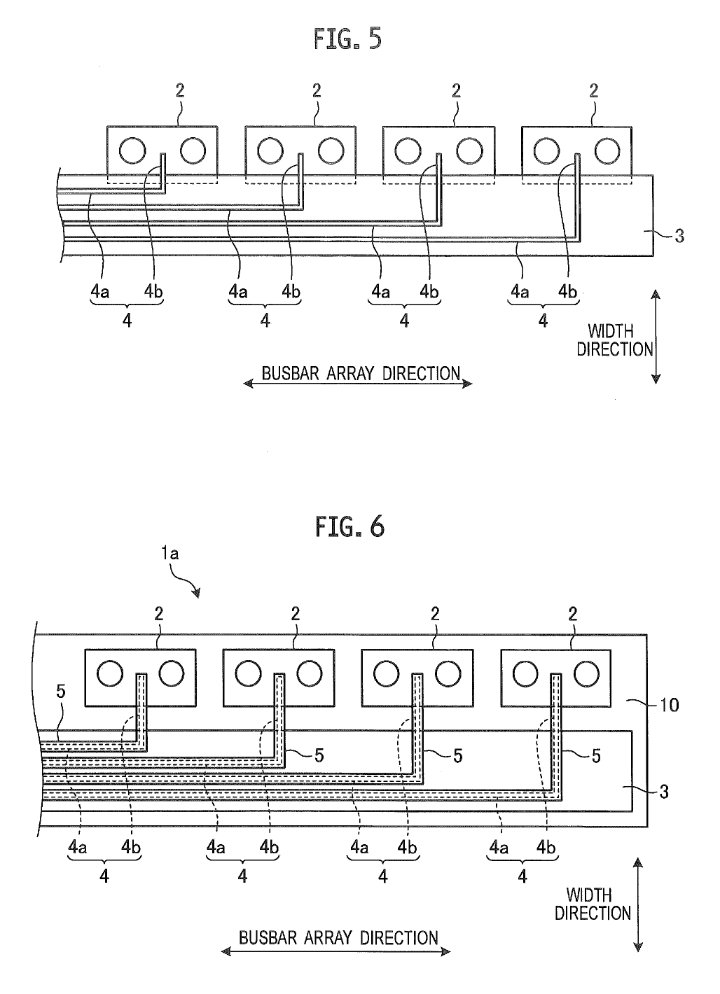

Next, a description will be made of a production process for the printed circuit body 1 according to the first embodiment with reference to FIGS. 3 to 5. FIG. 3 is a flowchart showing the production process for the printed circuit body according to the first embodiment. FIG. 4 is a schematic view for explaining a process of Step S101 of the flowchart of FIG. 3. FIG. 5 is a schematic view for explaining a process of Step S102 of the flowchart of FIG. 3. Note that FIG. 1 mentioned above is also referred to here since FIG. 1 is also a schematic view for explaining a process of Step S104 of the flowchart of FIG. 3. Hereinafter, a description will be made of the production process for the printed circuit body 1 in accordance with the flowchart of FIG. 3 while referring to FIGS. 1, 4 and 5.

In Step S101, the busbars 2 and the insulator layer 3 are molded integrally with each other by insert molding. Specifically, the plurality of busbars 2 are arranged in parallel to one another along the busbar array direction, and the one-side end portions in the width direction of these busbars 2 are wrapped by a molten material of the insulator layer 3 and are solidified, whereby the busbars 2 and the insulator layer 3 are molded integrally with each other. In FIG. 4, four busbars 2 are arranged in parallel to one another. As shown in FIG. 4, the busbars 2 and the insulator layer 3, which are molded integrally with each other, are formed into a band shape in which the insulator layer 3 is extended in the busbar array direction. Here, the plurality of busbars 2 are partially embedded in the one-side end surface in the width direction of the insulator layer 3. When such processing of Step S101 is completed, the production process proceeds to Step S102.

In Step S102, the conductor layers 4 which integrally cover the busbars 2 and the insulator layer 3 are formed by printing. The conductor layers 4 are formed by the same number as that of the busbars 2. In FIG. 5, four conductor layers 4 and four busbars 2 are formed. Each of the plurality of conductor layers 4 is individually connected to any one of the plurality of busbars 2. As shown in FIG. 5, in each of the conductor layers 4, the main line portion 4a of the conductor layer 4 is formed in a line shape so as to be extended on the insulator layer 3 along the busbar array direction. Moreover, in each of the conductor layers 4, the connection line portion 4b of the conductor layer 4 is formed into such a line shape that the connection line portion 4b is bent from the main line portion 4a at substantially right angle in the direction of any one of the busbars 2 and is extended in the width direction of the insulator layer 3 until reaching the front surface of the busbar 2. In this process, for example, the conductive paste is printed by using a screen printer, whereby the conductor layers 4 are superimposed and disposed on the front surface side in the lamination direction of the busbars 2 and the insulator layer 3. As the screen printer, for example, DP-320 made by Newlong Seimitsu Kogyo Co., Ltd. is used. As the conductive paste, for example, Ag paste CA-6178 made by Daiken Chemical Co., Ltd. is used. When such processing of Step S102 is completed, the production process proceeds to Step S103.

In Step S103, the conductor layers 4 are baked. By this baking processing, conductivity can be imparted to the conductor layers 4. In this baking process, for example, the conductor layers 4 are heated for 30 minutes by using a hot air dryer of 150° C. When such processing of Step S103 is completed, the production process proceeds to Step S104.

In Step S104, the resist layers 5 which cover the conductor layers 4 are formed. The resist layers 5 are formed by the same number as that of the busbars 2 and the conductor layers 4. In the printed circuit body 1 shown in FIG. 1, four resist layers 5 are formed. Each of the resist layers 5 is formed on the front surface side in the lamination direction of the plurality of conductor layers 4 so as to cover the entire area of any one of the plurality of conductor layers 4. That is to say, as shown in FIG. 1, each of the resist layers 5 is formed in such a line shape that is extended along the busbar array direction so as to cover the main line portion 4a of the conductor layer 4, and in addition, is formed in such a line shape that is extended along the width direction of the insulator layer 3 so as to cover the connection line portion 4b of the conductor layer 4. When such processing of Step S104 is completed, the production process proceeds to Step S105.

In Step S105, an evaluation of continuity is implemented, and continuity of the conductor layers 4 is confirmed. In the evaluation of continuity, a continuity test of the conductor layers 4, which uses a tester, is implemented, and continuity between a busbar 2-side end portion on one side of each of the conductor layers 4 and an insulator layer 3-side end portion on other side thereof is confirmed. When such processing of Step S105 is completed, the production process for the printed circuit body 1 is ended.

### <Effects>

Next, a description will be made of effects of the printed circuit body 1 according to the first embodiment.

The printed circuit body 1 of the first embodiment includes: the busbars 2 electrically connected to the connection targets such as the terminals of the batteries; the insulator layer 3 having insulating properties; and the conductor layers 4, which integrally cover the busbars 2 and the insulator layer 3, and are electrically connected to the busbars 2.

By this configuration, the conductor layers 4 integrally cover the busbars 2 and the insulator layer 3, and accordingly, it becomes unnecessary to perform wiring work in order to electrically connect the busbars 2 and the conductor layers 4 to each other like the conventional busbar module. In this way, if the printed circuit body 1 is produced, it becomes possible to simultaneously implement the connection between the busbars 2 and the conductor layers 4 and the circuit formation, and as a result, a wiring structure between the busbars 2 and the conductor layers 4 can be formed with ease. That is to say, in accordance with the printed circuit body 1 of the first embodiment, such effects are exerted that it becomes possible to simultaneously implement connection between the metal members 2 and the conductor layers 4 and the circuit formation, and that a wiring structure between the metal members 2 and the conductor layers 4 can be formed with ease.

Moreover, the printed circuit body 1 of the first embodiment includes the resist layers 5 which cover and protect the conductor layers 4. By this configuration, in accordance with the printed circuit body 1 of the first embodiment, the conductor layers 4 are not exposed to the outside, and can be protected by the resist layers 5, and accordingly, the continuity of the conductor layers 4 can be suitably maintained.

Furthermore, in the printed circuit body 1 of the first embodiment, the busbars 2 and the insulator layer 3 are formed integrally with each other by insert molding. The conductor layers 4 integrally cover the busbars 2 and the insulator layer 3 while including the connection portions therebetween. By this configuration, the busbars 2 and the insulator layer 3 can be molded integrally with each other, and accordingly, the number of components can be reduced at the time of producing the printed circuit body 1. Moreover, relative positions between the busbars 2 and the insulator layer 3 can be fixed, and accordingly, it can be made easy to form the conductor layers 4 on the busbars 2 and the insulator layer 3. Hence, in accordance with the printed circuit body 1 of the first embodiment, workability can be enhanced.

Moreover, in the printed circuit body 1 of the first embodiment, the conductor layers 4 are formed by printing. By this configuration, in accordance with the printed circuit body 1 of the first embodiment, the conductor layers 4 can be formed with ease while setting the shape and arrangement thereof as desired.

Furthermore, in the printed circuit body 1 of the first embodiment, the conductor layers 4 are formed so as to conduct by printing the conductive paste and thereafter baking the same. The conductive paste is any of the Ag paste, the Cu paste and the Au paste, which contain silver (Ag), copper (Cu) and gold (Au) as main metal components, respectively, or the mixed paste obtained by mixing two or more types of these. By this configuration, in accordance with the printed circuit body 1 of the first embodiment, the conductivity of the conductor layers 4 can be further enhanced.

Moreover, in the printed circuit body 1 of the first embodiment, the insulator layers 3 are formed of any of the materials, which are polyvinyl chloride (PVC), polypropylene (PP), polyethylene terephthalate (PET), polyethylene naphthalate (PEN), polycarbonate (PC), polybutylene terephthalate (PBT), and polyethylene (PE). By this configuration, in accordance with the printed circuit body 1 of the first embodiment, the insulating properties of the insulator layers 3 can be further enhanced.

### Second Embodiment

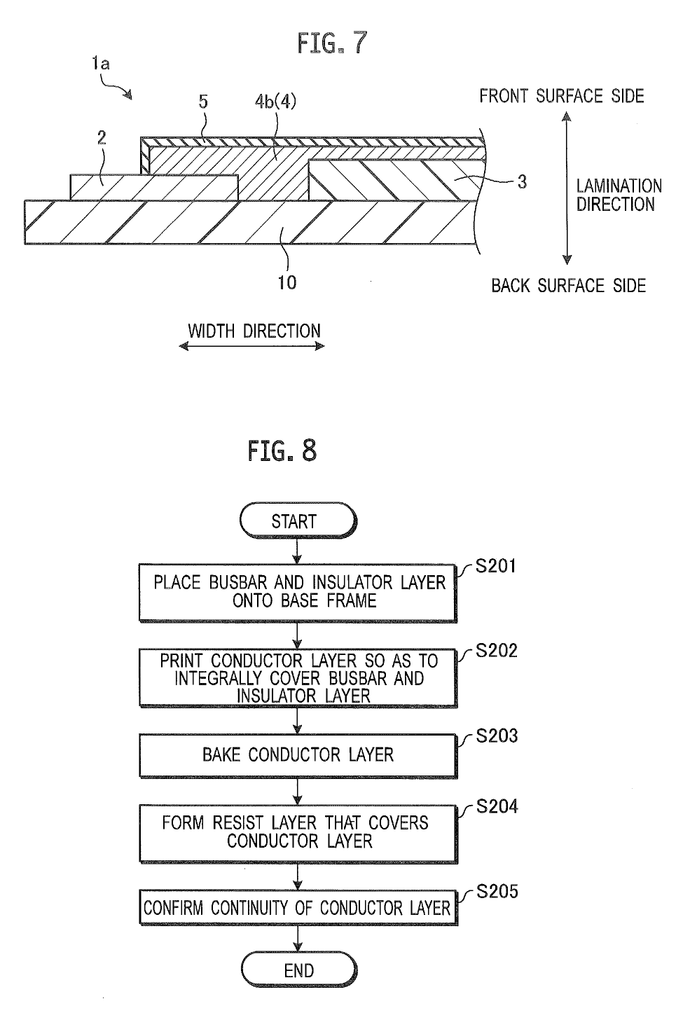

Next, a description will be made of a second embodiment with reference to FIG. 6 to FIG. 10. First, a description will be made of a configuration of a printed circuit body 1a according to the second embodiment with reference to FIGS. 6 and 7. FIG. 6 is a plan view showing a schematic configuration of the printed circuit body according to the second embodiment of the present invention. FIG. 7 is a cross-sectional view showing a cross-sectional shape perpendicular to a busbar array direction of the printed circuit body shown in FIG. 6.

As shown in FIGS. 6 and 7, the printed circuit body 1a includes: the busbars 2; the insulator layer 3; the conductor layers 4; the resist layers 5; and a base frame 10 as an insulating support. In terms of a configuration, the printed circuit body 1a of the second embodiment is different from the printed circuit body 1 of the first embodiment in a point that the busbars 2 and the insulator layer 3 are not molded integrally with each other but are arranged apart from each other, and in a point that the conductor layers 4 also integrally cover the base frame 10 that is interposed between the busbars 2 and the insulator layers 3.

The base frame 10 is a substrate, in which the busbars 2, the insulator layer 3 and the conductor layers 4 are arranged on a front surface, the substrate coupling the conductor layers 4 to the busbars 2. The base frame 10 is formed by using an insulating material similar to that of the insulator layer 3. The material of the base frame 10 may be the same as or different from the material of the insulator layer 3. As shown in FIG. 6 and FIG. 7, the busbars 2 and the insulator layer 3 are placed on a principal plane on a front surface side in the lamination direction of the base frame 10 so as to be spaced apart from each other. That is to say, the principal plane of the base frame 10 is exposed between the busbars 2 and the insulator layer 3. In this way, when the conductor layers 4 are formed on this front surface, then as shown in FIG. 7, the obtained conductor layers 4 become conductor layers which integrally cover the busbars 2, the base frame 10 and the insulator layer 3.

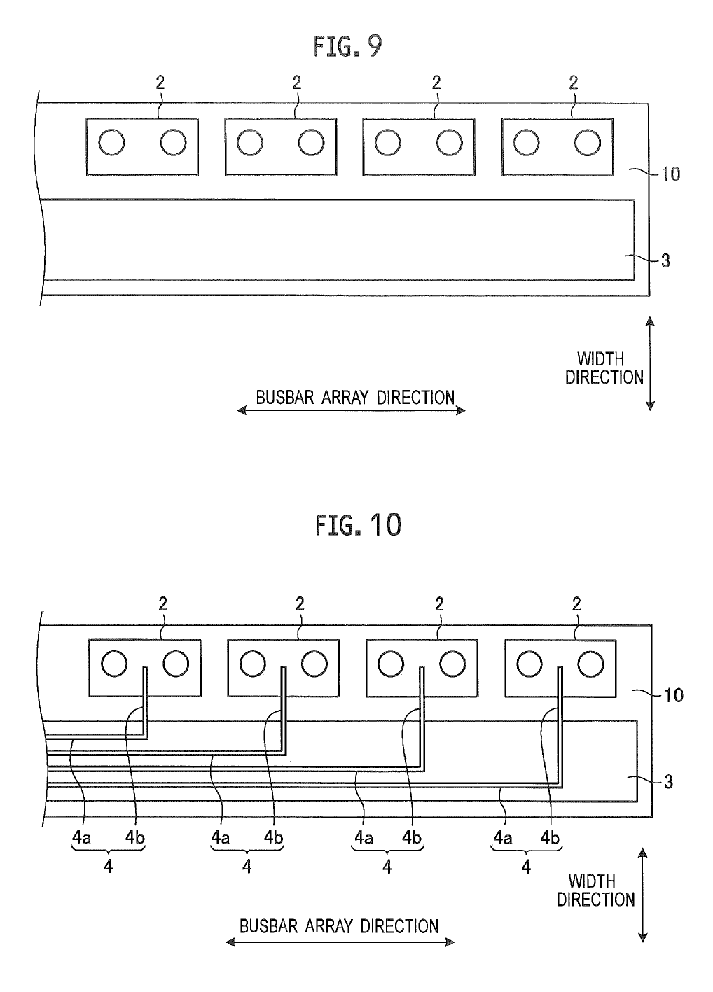

Next, a description will be made of a production process for the printed circuit body 1a according to the second embodiment with reference to FIGS. 8 to 10. FIG. 8 is a flowchart showing the production process for the printed circuit body according to the second embodiment. FIG. 9 is a schematic view for explaining a process of Step S201 of the flowchart of FIG. 8. FIG. 10 is a schematic view for explaining a process of Step S202 of the flowchart of FIG. 8. Note that FIG. 6 mentioned above is also referred to here since FIG. 6 is also a schematic view for explaining a process of Step S204 of the flowchart of FIG. 8. Hereinafter, a description will be made of the production process for the printed circuit body 1a in accordance with the flowchart of FIG. 8 while referring to FIGS. 6, 9 and 10.

In Step S201, the busbars 2 and the insulator layers 3 are placed on the base frame 10. As shown in FIG. 9, on the principal plane on the front surface side in the lamination direction of the base frame 10, a plurality of the busbars 2 are placed in parallel to one another along the busbar array direction. In FIG. 9, four busbars 2 are placed in parallel to one another. Moreover, in the same way, on the principal plane on the front surface side in the lamination direction of the base frame 10, the insulator layer 3 is placed so as to be extended along the busbar array direction apart from these busbars 2 by a predetermined distance in the width direction. Note that, in this process, the busbars 2 and the insulator layer 3 may be adhered onto the base frame 10, or may be fastened to the base frame 10 by screws and the like. When such processing of Step S201 is completed, the production process proceeds to Step S202.

In Step S202, the conductor layers 4 are formed by printing so as to integrally cover the busbars 2 and the insulator layer 3. The conductor layers 4 are formed by the same number as that of the busbars 2. In FIG. 10, four conductor layers 4 and four busbars 2 are formed. Each of the plurality of conductor layers 4 is individually connected to any one of the plurality of busbars 2. As shown in FIG. 10, in each of the conductor layers 4, the main line portion 4a of the conductor layer 4 is formed in a linear shape so as to be extended on the insulator layer 3 along the busbar array direction. Moreover, in each of the conductor layers 4, the connection line portion 4b of the conductor layer 4 is formed into such a line shape that the connection line portion 4b is bent from the main line portion 4a at substantially right angle in the direction of any one of the busbars 2 and is extended in the width direction of the insulator layer 3 until reaching the front surface of the busbar 2. That is to say, each of the connection line portions 4b of the conductor layer 4 integrally covers the insulator layer 3, the base frame 10 and the busbar 2 along the width direction. In this process, for example, the conductive paste is printed by using a dispenser, whereby the conductor layers 4 are superimposed and disposed on the front surface side in the lamination direction of the busbars 2, the base frame 10 and the insulator layer 3. As the dispenser, for example, a high-performance screw dispenser SCREW MASTER 2 made by Musashi Engineering Co., Ltd. is used. As the conductive paste, for example, Ag paste RA FS 074 made by TOYOCHEM Co., Ltd. is used. When such processing of Step S202 is completed, the production process proceeds to Step S203.

In Step S203, the conductor layers 4 are baked. By this baking processing, conductivity can be imparted to the conductor layers 4. In this process, for example, the conductor layers 4 are heated for 30 minutes by using a hot air dryer of 150° C. When such processing of Step S203 is completed, the production process proceeds to Step S204.

In Step S204, the resist layers 5 which cover the conductor layers 4 are formed. The resist layers 5 are formed by the same number as that of the busbars 2 and the conductor layers 4. In the printed circuit body 1a shown in FIG. 6, four resist layers 5 are formed. Each of the resist layers 5 is formed on the front surface side in the lamination direction of the plurality of conductor layers 4 so as to cover the entire area of any one of the plurality of conductor layers 4. That is to say, as shown in FIG. 6, each of the resist layers 5 is formed in such a line shape that is extended along the busbar array direction so as to cover the main line portion 4a of the conductor layer 4, and in addition, is formed in such a line shape that is extended along the width direction of the insulator layer 3 so as to cover the connection line portion 4b of the conductor layer 4. When such processing of Step S204 is completed, the production process proceeds to Step S205.

In Step S205, an evaluation of continuity is implemented, and the continuity of the conductor layers 4 is confirmed. In the evaluation of continuity, a continuity test of the conductor layers 4, which uses a tester, is implemented, and continuity between a busbar 2-side end portion on one side of each of the conductor layers 4 and an insulator layer 3-side end portion on other side thereof is confirmed. When such processing of Step S205 is completed, the production process for the printed circuit body 1a is ended.

### <Effects>

Next, a description will be made of effects of the printed circuit body 1a according to the second embodiment.

In a similar way to the printed circuit body 1 of the first embodiment, the printed circuit body 1a of the second embodiment includes: the busbars 2 electrically connected to the connection targets such as the terminals of the batteries; the insulator layer 3 having insulating properties; and the conductor layers 4, which integrally cover the busbars 2 and the insulator layer 3, and are electrically connected to the busbars 2. Moreover, the printed circuit body 1a of the second embodiment includes the resist layers 5 which cover and protect the conductor layers 4. Furthermore, in the printed circuit body 1a of the second embodiment, the conductor layers 4 are formed so as to conduct by printing the conductive paste and thereafter baking the same. Hence, in accordance with the printed circuit body 1a of the second embodiment, similar effects to those of the printed circuit body 1 of the first embodiment can be exerted. That is to say, in accordance with the printed circuit body 1a of the second embodiment, such effects are exerted that it becomes possible to simultaneously implement the connection between the metal members 2 and the conductor layers 4 and the circuit formation, and that the wiring structure between the metal members 2 and the conductor layers 4 can be formed with ease.

Moreover, the printed circuit body 1a of the second embodiment includes the base frame 10 on which the busbars 2 and the insulator layer 3 are placed. Moreover, the busbars 2 and the insulator layer 3 are placed on the principal plane on the front surface side in the lamination direction of the base frame 10 so as to be spaced apart from each other. The conductor layers 4 are formed so as to integrally cover the busbars 2, the base frame 10 and the insulator layer 3. In accordance with this configuration, the busbars 2 and the insulator layer 3 are arranged on the base frame 10, whereby the relative positions between the busbars 2 and the insulator layer 3 can be set constant with ease, and accordingly, it can be made easy to form the conductor layers 4 between the busbars 2 and the insulator layer 3, and the workability can be enhanced.

Note that the printed circuit body 1a of the second embodiment can also adopt a configuration in which the base frame 10 and the insulator layer 3 are formed collectively as a single member. In other words, the printed circuit body 1a of the second embodiment can also adopt a configuration, in which the insulator layer 3 is eliminated from the printed circuit body 1a of the second embodiment, and the conductor layers 4 are directly formed on the base frame 10. In this case, the base frame 10 also serves as such an insulator layer on which the main line portions 4a of the conductor layers 4 are arranged. The connection line portions 4b of the conductor layers 4 are formed along the width direction so as to integrally cover the base frame 10 and the busbars 2.

In the first and second embodiments, such configurations are illustrated, in which the printed circuit bodies 1 and 1a according to the embodiments are applied as the busbar modules for a power supply device. However, the printed circuit bodies 1 and 1a can also be applied to other than the busbar modules.

Moreover, the busbars 2 just need to be metal members which electrically connect the connection targets such as the terminals of the batteries and the conductor layers 4. For example, the busbars 2 may have a shape other than the rectangular plate shape, or may be replaced by metal members which have a function other than that of the busbars 2 (terminals).

Moreover, in the first and second embodiments, such configurations, in each of which the resist layers 5 are provided as the elements which protect the conductor layers 4, are illustrated. However, the first and second embodiments can also adopt configurations, in which the resist layers 5 which protect the conductor layers 4 are not provided in response to a usage environment of the printed circuit bodies 1 and 1a according to the embodiments.

Furthermore, in the first and second embodiments, such configurations, in each of which the resist layers 5 are provided as the elements which protect the conductor layers 4, are illustrated. However, in the first and second embodiments, such configurations may be used, in each of which an insulating cover that covers an entirety of the busbars 2 and the insulator layer 3 is used in place of the resist layers 5. As the insulating cover, it is preferable to use PET, PEN, PC, PP, PBT, PU and the like, each of which has an adhesive material on one-surface side in contact with the insulator layers 3.

Moreover, in the first and second embodiments, such configurations, in each of which the conductor layers 4 are formed by printing, are illustrated. However, in the first and second embodiments, the conductor layers 4 may be formed by a method other than printing as long as the conductor layers 4 integrally cover the busbars 2 and the insulator layer 3 and the main line portions 4a and the connection line portions 4b can be integrally formed.

Moreover, in the first and second embodiments, such configurations, in each of which the busbars 2 and the insulator layer 3 are integrally formed by insert molding, are illustrated. However, in the first and second embodiments, the busbars 2 and the insulator layer 3 may be integrally formed by laminating molding, extrusion molding, presswork, adhesion work and the like.

The description has been made above of the present invention by the embodiments; however, the present invention is not limited to these, and is modifiable in various ways within the scope of the spirit of the invention.

### EXAMPLES

The present invention will be described below more in detail by examples; however, the present invention is not limited to these examples.

In the following examples, the following conductive pastes were used as the circuit-forming conductive paste or the mounting conductive paste.

(1) Conductive paste A: Ag paste RAFS 074 (curable at 100° C.; viscosity at 25° C.: 130 Pa·S) made by Toyochem Co., Ltd.
(2) Conductive paste B: Ag paste CA-6178 (curable at 130° C.; viscosity at 25° C.: 195 Pa·S) made by Daiken Chemical Co., Ltd.
(3) Conductive paste C: Ag ink Metalon (registered trademark) HPS-030LV (curable at 80 to 130° C.; viscosity exceeding 1000 cP) made by NovaCentrix Corporation
(4) Conductive paste D: through hole-ready Cu paste CP 700 (viscosity at 25° C.: 3 Pa·S) made by Harima Chemicals Group, Inc.

### Example 1

### Circuit Forming Step

First, a film-like polyethylene terephthalate (PET) substrate (Lumirror S10 made by Toray Industries, Inc.; melting point: 260° C.) with a thickness of 50 μm was prepared. Next, onto a front surface of the PET substrate, the conductive paste A was applied as the circuit-forming conductive paste by screen printing. The PET substrate applied with the conductive paste A was disposed into a microwave-discharged plasma baking device (Micro Labo PS-2 made by Nisshin Inc.), and was subjected to plasma baking under conditions shown in Table 1. After the plasma baking, a circuit made of Ag with a thickness of 10 to 20 μm was formed on the front surface of the PET substrate.

### (Insulating Cover Layer Forming Step)

Screen printing of the epoxy-based resist NPR-3400 made by Nippon Polytech Corp. was performed for a front surface of the circuit by using a screen plate in which portions to have mounted components placed thereon and terminal portions are made open, and the epoxy-based resist was dried for 20 minutes at 80° C. by a hot air dryer.

### (Electronic Component Mounting Step)

Next, the conductive paste A was applied as the mounting conductive paste onto the above-described circuit, and an LED SMLZ14WBGDW(A) (longitudinal 2.8 mm×lateral 3.5 mm×thickness 1.9 mm) made by ROHM Co., Ltd. was mounted on an applied film.

Then, into the above-described microwave-discharged plasma baking device, the PET substrate, in which the conductive paste A was applied onto the circuit and the electronic component was placed thereon, was disposed, and was subjected to the plasma baking under production conditions shown in Table 1. After the plasma baking, a film-like printed circuit board was obtained, in which the electronic component was mounted on the front surface of the circuit via the electronic component bonding layer made of Ag.

TABLE 1

| | | | | | | Example | | | | | | | | | | | | |
|---|---|---|---|---|---|---|---|---|---|---|---|---|---|---|---|---|---|---|
| | | | | | | 1 | 2 | 3 | 4 | 5 | 6 | 7 | 8 | 9 | 10 | 11 | 12 | 13 |
| Production | Circuit | Type of Conductive Paste | | | | A | A | A | A | A | A | A | A | A | A | B | D | D |
| Condition | Formation | Plasma | Composition | H₂ | (mass %) | 2 | 2 | 2 | 100 | 50 | 0 | 0 | 0 | 2 | 2 | 2 | 100 | 100 |
| | | Baking | of Process | N₂ | (mass %) | 98 | 98 | 98 | 0 | 50 | 100 | 97 | 97 | 98 | 98 | 98 | 0 | 0 |
| | | | Gas | He | (mass %) | 0 | 0 | 0 | 0 | 0 | 0 | 0 | 3 | 0 | 0 | 0 | 0 | 0 |
| | | | | Ar | (mass %) | 0 | 0 | 0 | 0 | 0 | 0 | 3 | 0 | 0 | 0 | 0 | 0 | 0 |
| | | | Power | | (KW) | 4 | 4 | 4 | 4 | 4 | 4 | 4 | 4 | 4 | 4 | 4 | 4 | 4 |
| | | | Baking Time | | (min.) | 2 | 1 | 4 | 4 | 4 | 4 | 4 | 4 | 2 | 2 | 2 | 2 | 2 |
| | Electronic | Type of Conductive Paste | | | | A | A | A | A | A | A | A | A | B | C | B | D | A |
| | Component | Plasma | Composition | H₂ | (mass %) | 2 | 2 | 2 | 100 | 100 | 100 | 100 | 100 | 2 | 2 | 2 | 100 | 100 |
| | Mounting | Baking | of Process | N₂ | (mass %) | 98 | 98 | 98 | 0 | 0 | 0 | 0 | 0 | 98 | 98 | 98 | 0 | 0 |
| | | | Gas | He | (mass %) | 0 | 0 | 0 | 0 | 0 | 0 | 0 | 0 | 0 | 0 | 0 | 0 | 0 |
| | | | | Ar | (mass %) | 0 | 0 | 0 | 0 | 0 | 0 | 0 | 0 | 0 | 0 | 0 | 0 | 0 |

| | | | | | | | | | | | | | | |
|---|---|---|---|---|---|---|---|---|---|---|---|---|---|---|
| Power | (KW) | 4 | 4 | 4 | 4 | 4 | 4 | 4 | 4 | 4 | 4 | 4 | 4 | 4 |
| Baking Time | (min.) | 2 | 1 | 4 | 4 | 4 | 4 | 4 | 4 | 2 | 2 | 2 | 2 | 2 |

| | | | | | | | | | | | | | | |
|---|---|---|---|---|---|---|---|---|---|---|---|---|---|---|
| Evaluation | Substrate Deformation | ◯ | ◯ | ◯ | ◯ | ◯ | ◯ | ◯ | ◯ | ◯ | ◯ | ◯ | ◯ | ◯ |
| Result | Bonding Strength | ◯ | ◯ | ◯ | ◯ | ◯ | ◯ | ◯ | ◯ | ◯ | ◯ | ◯ | ◯ | ◯ |
| | Bonding State between Circuit and Electronic | ◯ | ◯ | ◯ | ◯ | ◯ | ◯ | ◯ | ◯ | ◯ | ◯ | ◯ | ◯ | ◯ |
| | Component Bonding Layer | | | | | | | | | | | | | |
| | Conductivity | ◯ | ◯ | ◯ | ◯ | ◯ | ◯ | ◯ | ◯ | ◯ | ◯ | ◯ | ◯ | ◯ |

### (Evaluation)

For the PET substrate in which the electronic component was mounted on the front surface of the circuit, substrate deformation, bonding strength of the mounted component, a bonding state between the circuit and the electronic component bonding layer, and conductivity were evaluated.

### <Substrate Deformation>

With regard to the substrate deformation, it was visually evaluated whether or not there occurred a change in a height direction of the substrate owing to waviness and the like of the substrate. One in which there occurred no change in the height direction of the substrate was evaluated to be good (shown by a circle symbol), and one in which there occurred a change in the height direction of the substrate was evaluated to be defective (shown by a cross symbol).

### <Bonding Strength of Mounted Component>

The bonding strength of the mounted component was evaluated in conformity with JIS Z 3198-7. Specifically, tensile strength when the LED SMLZ14WBGDW(A) made by ROHM Co., Ltd., in which dimensions are: longitudinal 2.8 mm×lateral 3.5 mm×thickness 1.9 mm, was pulled and peeled in a direction parallel to the front surface of the circuit, was measured and evaluated. One in which the tensile strength was 20 MPa or more was evaluated to be good (shown by a circle symbol), and one in which the tensile strength was less than 20 MPa was evaluated to be defective (shown by a cross symbol).

### <Bonding State Between Circuit and Electronic Component Bonding Layer>

By using a cross section picture (500 magnifications) of such a sample, a bonding state of an interface between the circuit and the electronic component bonding layer was observed, and it was evaluated whether or not the metal particles composing the circuit and the metal particles composing the electronic component bonding layer were coupled to each other. One in which the metal particles composing the circuit and the metal particles composing the electronic component bonding layer were coupled to each other without gap was evaluated to be good (shown by a circle symbol), and one in which the interface has a gap partially or entirely and no coupling was made was evaluated to be defective (shown by a cross symbol).

### <Conductivity>

An LED switch using the LED (SMLZ14WBGDW(A) made by ROHM Co., Ltd. was connected between two pads on the sample. Next, it was confirmed whether or not the LED turned on when the LED switch was energized by 3 V so that a current of 12 mA could flow therethrough. One in which the LED turned on was evaluated to be good (shown by a circle symbol), and one in which the LED did not turn on was evaluated to be defective (shown by a cross symbol).

Table 1 shows results of the substrate deformation, the bonding strength of the mounted component, the bonding state between the circuit and the electronic component bonding layer, and the conductivity.

### Examples 2 to 17

Film-like printed circuit boards were fabricated in a similar way to Example 1 except that the production conditions were changed as shown in Table 1 or Table 2, and the fabricated film-like printed circuit boards were evaluated.

Table 1 and Table 2 show the production conditions and evaluation results.

TABLE 2

| | | | | | | | | | | Comparative | | |
|---|---|---|---|---|---|---|---|---|---|---|---|---|
| | | | | | | Example | | | | Example | | |
| | | | | | | 14 | 15 | 16 | 17 | 1 | 2 | 3 |
| Production | Circuit | Type of Conductive Paste | | | | A | A | A | D | A | A | A |
| Condition | Formation | Plasma | Composition | H₂ | (mass %) | 98 | 98 | 98 | 50 | — | — | — |
| | | Baking | of Process | N₂ | (mass %) | 2 | 2 | 2 | 50 | — | — | — |
| | | | Gas | He | (mass %) | 0 | 0 | 0 | 0 | — | — | — |
| | | | | Ar | (mass %) | 0 | 0 | 0 | 0 | — | — | — |
| | | | Power | | (KW) | 4 | 4 | 4 | 4 | — | — | — |
| | | | Baking Time | | (° C. ) | 5 | 1 | 4 | 2 | — | — | — |
| | | Heat | Baking | | | — | — | — | — | 150 | 150 | 110 |
| | | Baking | Temperature | | | | | | | | | |
| | | | Baking Time | | (min.) | — | — | — | — | 30 | 20 | 60 |
| | Electronic | Type of Conductive Paste | | | | A | A | A | A | A | A | A |
| | Component | Plasma | Composition | H₂ | (mass %) | 98 | 98 | 98 | 50 | — | — | — |
| | Mounting | Baking | of Process | N₂ | (mass %) | 2 | 2 | 2 | 50 | — | — | — |
| | | | Gas | He | (mass %) | 0 | 0 | 0 | 0 | — | — | — |
| | | | | Ar | (mass %) | 0 | 0 | 0 | 0 | — | — | — |

| | | | | | | | | | |
|---|---|---|---|---|---|---|---|---|---|
| | Power | (KW) | 4 | 4 | 4 | 4 | — | — | — |
| | Baking Time | | 5 min. | 10 sec. | 4 min. | 2 min. | — | — | — |
| Heat | Baking | (° C. ) | — | — | — | — | 150 | 150 | 150 |
| Baking | Temperature | | | | | | | | |
| | Baking Time | (min.) | — | — | — | — | 30 | 30 | 30 |

| | | | | | | | | |
|---|---|---|---|---|---|---|---|---|
| Evaluation | Substrate Deformation | X | ◯ | ◯ | ◯ | X | ◯ | ◯ |
| Result | Bonding Strength | ◯ | X | ◯ | ◯ | ◯ | X | X |
| | Bonding State between Circuit and Electronic | ◯ | X | ◯ | ◯ | ◯ | X | X |
| | Component Bonding Layer | | | | | | | |
| | Conductivity | ◯ | ◯ | ◯ | X | ◯ | X | X |

### Comparative Examples 1 to 3

Film-like printed circuit boards were fabricated in a similar way to Example 1 except that the production conditions were changed as shown in Table 2, and the fabricated film-like printed circuit boards were evaluated.

Specifically, the circuit forming step was performed in a similar way to Example 1 except that the baking of the circuit-forming conductive paste was performed by heat baking using an oven in place of the plasma baking. In Comparative example 1, heat baking at 150° C. for 30 minutes was performed. In Comparative example 2, heat baking at 150° C. for 20 minutes was performed. In Comparative example 3, heat baking at 110° C. for 60 minutes was performed. In a similar way to Example 1, the thickness of the circuit was set to 10 to 20 μm.

Moreover, the electronic component mounting step was performed in a similar way to Example 1 except that the baking of the mounting conductive paste was performed by the heat baking using an oven in place of the plasma baking after the circuit forming step. In each of Comparative examples 1 to 3, heat baking at 150° C. for 30 minutes was performed. Table 2 shows conditions of the heat baking.

Table 2 shows the production conditions and evaluation results.

From the results of Table 1 and Table 2, it is understood that the evaluation results are good in a case where the plasma baking is used for the baking of the circuit-forming conductive paste and the mounting conductive paste.

The film-like printed circuit board of this embodiment and the producing method therefor are used, for example, for a wire harness of an automobile and a component related thereto. As the component related to the wire harness, for example, an ECU of a vehicle is mentioned. The printed circuit body of this embodiment is used, for example for the ECU of the vehicle.

In accordance with the film-like printed circuit board according to the present invention, there is obtained the film-like printed circuit board capable of forming the circuit and mounting the electronic component thereon in a short time at a low temperature by using the versatile low-melting-point substrate.

In accordance with the method for producing the film-like printed circuit board according to the present invention, the film-like printed circuit board can be produced by forming the circuit and mounting the electronic component thereon in a short time at a low temperature by using the versatile low-melting-point substrate.

What is claimed is:

1. A film-like printed circuit board comprising:
a low-melting-point resin film substrate composed of a low-melting-point resin in which a melting point is 370° C. or less;
a circuit having a thickness of 10 to 20 μm and formed in a manner that a circuit-forming conductive paste applied onto the low-melting-point resin film substrate is subjected to plasma baking;
an electronic component bonding layer formed in a manner that a mounting conductive paste applied onto the circuit is subjected to the plasma baking; and
an electronic component mounted on the circuit via the electronic component bonding layer.

2. The film-like printed circuit board according to claim 1, wherein the plasma baking for forming the circuit or the electronic component bonding layer is microwave-discharged plasma baking of irradiating plasma generated by microwave discharge.

3. The film-like printed circuit board according to claim 1,
wherein the circuit-forming conductive paste is a conductive paste that contains powder of one or more types of metal selected from the group consisting of Ag, Cu and Au, and
the mounting conductive paste is a conductive paste that contains power of one or more types of metal selected from the group consisting of Ag, Cu and Au.

4. The film-like printed circuit board according to claim 1, wherein a thickness of the low-melting-point resin film substrate is 50 μm or more.

5. The film-like printed circuit board according to claim 1, wherein the low-melting-point resin film substrate is composed of polyethylene terephthalate (PET), polybutylene terephthalate (PBT), polyethylene naphthalate (PEN), polypropylene (PP), or polycarbonate (PC).

6. A method for producing a film-like printed circuit board comprising:
a step of applying a circuit-forming conductive paste onto a low-melting-point resin film substrate composed of a low-melting-point resin in which a melting point is 370° C. or less, and performing plasma baking for the applied circuit-forming conductive paste, thereby forming a circuit having a thickness of 10 to 20 μm; and
a step of applying an mounting conductive paste onto the circuit, placing an electronic component onto a mounting conductive paste, and performing plasma baking for the applied mounting conductive paste, thereby mounting the electronic component on the circuit via an electronic component bonding layer.
